(19) United States
(12) Patent Application Publication
(10) Pub. No.: US 2012/0126203 A1
(43) Pub. Date: May 24, 2012

(54) High Power LED Device Architecture Employing Dielectric Coatings and Method of Manufacture

(75) Inventor: Jamie Knapp, Mendon, MA (US)

(73) Assignee: NEWPORT CORPORATION, Irvine, CA (US)

(21) Appl. No.: 13/387,704

(22) PCT Filed: Apr. 1, 2010
(86) PCT No.: PCT/US10/01009

§ 371 Date: Jan. 27, 2012

Related U.S. Application Data
(60) Provisional application No. 61/273,340, filed on Aug. 3, 2009.
(60) Provisional application No. 61/280,540, filed on Nov. 4, 2009.
(60) Provisional application No. 61/335,160, filed on Dec. 30, 2009.

(51) Int. Cl. H01L 33/04; H01L 33/52

(52) U.S. Cl. 257/13; 438/27; 257/E33.008; 257/E33.059; 257/E33.073

(57) ABSTRACT

An improved LED device is disclosed and includes at least one active layer in communication with an energy source and configured to emit a first electromagnetic signal within a first wavelength range and at least a second electromagnetic signal within at least a second wavelength range, a substrate configured to support the active layer, at least one coating layer applied to a surface of the substrate, the coating layer, configured for 0-90 degree incidence, to reflect at least 95% of the first electromagnetic signal at the first wavelength range and transmit at least 95% of the second electromagnetic signal at the second wavelength range, at least one metal layer applied to the coating layer and configured to transmit the second electromagnetic signal at the second wavelength range therethrough, and an encapsulation device positioned to encapsulate the active layer.

### BACKGROUND

The present application is a continuation of Patent Cooperation Treaty (PCT) Application PCT/US10/001009 filed Apr. 1, 2010, entitled “High Power LED Device Architectures Employing Dielectric Coatings and Method of Manufacture,” which in turn claims priority to U.S. Provisional Patent Application No. 61/273,340, filed Aug. 3, 2009, entitled “High Power LED Device Architectures Employing Dielectric Coatings and Method of Manufacture,” and U.S. Provisional Patent Application No. 61/280,540, filed Nov. 4, 2009, entitled “High Power LED Device Architectures Employing Dielectric Coatings and Method of Manufacture,” and U.S. Provisional Patent Application No. 61/335,160, filed Dec. 30, 2009, entitled “High Performance LED Optical Coatings and Methods of Use.” The entire contents of the aforementioned patent applications are hereby incorporated by reference in their entirety herein.

### BACKGROUND

Light emitting diodes (hereinafter LED) are electronic light sources having relatively intense luminescent output in the UV, visible and infrared wavelengths. Presently, there are many advantages of these devices over conventional lighting methods such as incandescent sources. Exemplary advantages of LED devices include lower energy consumption, extended lifetimes, improved robustness, smaller size and quicker switching. Red, green and blue LEDs have been commonplace for many years and are presently used in a multitude of applications including display lighting, biomedical fluorescence instrumentation and a vast array of commercial applications. Recently, the use of new high output white LEDs have grown significantly. Common uses for these white-light LEDs include architectural applications, automotive applications and other lighting uses. To be competitive with other lighting sources, white-light LEDs must achieve optimal efficiency. Ideally, high power LED (hereinafter HPLED) manufacturers hope to provide white-light LEDs having efficiencies of about 150 L/W or greater.

White LEDs are generally produced by altering the structure of blue LEDs. Blue LEDs are manufactured from wide bandgap semiconductor epitaxial materials such as Indium Gallium Nitride (InGaN). By employing fluorescence, the blue spectral output of the LED is converted to white light by the absorption of the blue photons into the encapsulant, which subsequently fluoresces white. FIGS. 1-3 show a cross-sectional view of a typical white light LED. As shown, the LED device 1 includes at least one light-producing active layer 3 positioned on a substrate 5. Exemplary substrates typically include silica substrates and sapphire substrates, as well as other materials. A reflective metal layer 7 is applied to a surface of the substrate 5. Further, a doped encapsulation device 9 is applied to the structure thereby sealing the light-producing active layer 3 within the structure. Typical doping materials include phosphor and other materials configured to fluoresce to produce white light when illuminated with a specific wavelength. For example, phosphor may be configured to fluoresce when illuminated with light 11 having a wavelength of about 450 nm.

As shown in FIG. 2, the blue spectral output of the LED device 1 is multidirectional. Some electromagnetic radiation 11a having a wavelength capable of resulting in fluorescence is emitted directly to the doped encapsulation device 9 thereby causing the doping material to fluoresce generally white light. Further, due to the multidirectional output of the light-producing active layer 3, rear-emitted light 11b is reflected by the metal layer 7 applied to the substrate 5 and direct to the encapsulation device 9. This reflected output 13b also results in fluoresces the doping material of the encapsulation device 9. While the metal layer 7 is somewhat useful in increasing the output of the LED device 1, a number of shortcomings have been identified. For example, the metal layer 7 may reflect about 85% to 90% of the incident light capable of fluorescing the doping materials in the encapsulation device 9. As such, the efficiency (e.g. L/W) of these LED devices 1 is not optimal. Ideally, the metal layer 7 would have a reflectivity approaching 100% at a wavelength to effect fluorescents of the doping materials, which to date has proven to be unattainable. As stated above, presently available devices include an aluminum layer 7 capable of reflecting about 85% to about 90% of incident light. Further, as shown in FIG. 2, some of the rear-emitted light 11c may be incident on the reflective aluminum layer 7 at various angles. Ideally, the reflective layer 7 would be capable of reflecting about 100% of the rear-emitted light 11c at all possible angles of incidence, thereby directing the reflected angular rear-emitted light 13c to the encapsulation device 9 and increasing device efficiency. Unfortunately, current-art metal reflector layers 7 suffer additional reflective losses at such extreme angles, resulting in an even poorer LED light output.

In addition to reflecting the rear-emitted light, the metal reflective material 7 may also behave as a heat-sink to enhance the thermal characteristics of the device. For example, the reflective material 7 may comprise aluminum and may be configured to enable the efficient transfer of heat from the substrate 5 to a mounting structure (not shown). For example, as shown in FIG. 3 undesirable infrared radiation 15 may be produced by the light-producing active layer 3 when an electrical charge is applied thereto. In one embodiment, the substrate 5 is configured to dissipate the heat therethrough. As such, the substrate 5 may form a heat sink. Further, the reflective layer 7 applied to the substrate 5 may also be configured to transfer heat therethrough. However, at least some infrared radiation 15 may be reflected by the reflective material 7 or at the substrate-reflective material interface. For example, in some applications approximately 20% of the infrared radiation 15 may be reflected back to the light-producing active layer 3 by the reflective layer 7 or the substrate-reflective layer interface. This reflected infrared radiation 17 may result in a degradation of the performance of the LED device 1. In severe cases, the reflected infrared radiation 17 may result in the catastrophic failure of the LED device 1 due to excessive heating.

Thus, in light of the foregoing, there is an ongoing need high power LED devices offering higher efficiency than presently available.

### SUMMARY

The present application disclosed various embodiments of improved LED device architectures and various methods for the manufacture thereof. Unlike prior art devices, the device architectures disclosed herein include at least one coating layer applied to the substrate configured to improve device efficiency and brightness.

More specifically, in one embodiment, an improved LED device is disclosed and includes at least one active layer in communication with an energy source and configured to emit a first electromagnetic signal within a first wavelength range and at least a second electromagnetic signal within at least a second wavelength range, a substrate configured to support the active layer, at least one coating layer applied to a surface of the substrate, the coating layer configured to reflect at least 95% of the first electromagnetic signal at the first wavelength range and transmit at least 95% of the second electromagnetic signal at the second wavelength range, and an encapsulation device positioned to encapsulate the active layer

In another embodiment, an improved LED device is disclosed and includes at least one active layer in communication with an energy source and configured to emit a first electromagnetic signal within a first wavelength range and at least a second electromagnetic signal within at least a second wavelength range, a substrate configured to support the active layer, at least one coating layer applied to a surface of the substrate, the coating layer configured to reflect at least 95% of the first electromagnetic signal at the first wavelength range at all angles from about 0 degree to about 90 degrees and optionally transmit at least 95% of the second electromagnetic signal at the second wavelength range applied to the coating layer and configured to transmit the second electromagnetic signal at the second wavelength therethrough, and an encapsulation device positioned to encapsulate the active layer.

In another embodiment, the present application discloses a method of manufacturing an LED device and includes growing an epitaxial layer capable of emitting electromagnetic radiation within a first wavelength range and at least a second electromagnetic radiation within at least a second wavelength range when subjected to an electric charge on a substrate, applying at least one coating layer configured to reflect at least 95% of the first electromagnetic signal at the first wavelength range and transmit at least 95% of the second electromagnetic signal at the second wavelength range to a surface of the substrate, and encapsulating at least the active layer within an encapsulation device.

In another embodiment, the present application discloses a method of manufacturing an LED device and includes growing an epitaxial layer capable of emitting electromagnetic radiation within a first wavelength range and at least a second electromagnetic radiation within at least a second wavelength range when subjected to an electric charge on a substrate, applying at least one coating layer configured to reflect at least 95% of the first electromagnetic signal at the first wavelength range and transmit at least 95% of the second electromagnetic signal at the second wavelength range to a surface of the substrate, applying at least one metal layer to the coating layer, and encapsulating at least the active layer within an encapsulation device.

Other features and advantages of the embodiments of the improved LED device architectures as disclosed herein will become apparent from a consideration of the following detailed description.

### BRIEF DESCRIPTION OF THE DRAWINGS

Various improved performance LED device architectures will be explained in more detail by way of the accompanying drawings, wherein:

FIG. 1 shows a cross-sectional view of an embodiment of a prior art LED device;

FIG. 2 shows a cross-sectional view of an embodiment of a prior art LED device during use wherein a portion of the electromagnetic radiation within a first wavelength range may be reflected by the metal layer;

FIG. 3 a cross-sectional view of an embodiment of a prior art LED device during use wherein a portion of the electromagnetic radiation within a second wavelength;

FIG. 4 shows a cross-sectional view of an embodiment of a novel LED device architecture having a coating layer applied to a surface of the substrate, the coating layer configured to improve the reflectance of the first electromagnetic radiation within a first wavelength range;

FIG. 5 shows a cross-sectional view of an alternate embodiment of a novel LED device architecture having a coating layer positioned at the active layer-substrate interface;

FIG. 6 shows a cross-sectional view of an alternate embodiment of a novel LED device architecture having a first coating layer positioned at the active layer-substrate interface and a second coating layer positioned at the substrate-metal/heat-sink layer interface;

FIG. 7 shows a cross-sectional view of the embodiment of the novel LED device architecture during use offering improved reflectance of the first electromagnetic signal;

FIG. 8 shows graphically the improved reflectance of the first electromagnetic signal of the novel LED device architecture during use as compared with prior art LED device architectures;

FIG. 9 shows a cross-sectional view of the embodiment of the novel LED device architecture during use offering improved transmission of the second electromagnetic signal;

FIG. 10 shows graphically the improved transmission of the second electromagnetic signal of the novel LED device architecture during use as compared with prior art LED device architectures;

FIG. 11 shows graphically the broad angle reflectance of the first electromagnetic signal of the novel LED device architecture as compared with prior art devices;

FIG. 12 shows graphically the broad angle reflectance of the novel LED device when the first electromagnetic signal has a wavelength of about 440 nm architecture as compared with prior art devices;

FIG. 13 shows graphically the broad angle reflectance of the novel LED device when the first electromagnetic signal has a wavelength of about 450 nm architecture as compared with prior art devices; and

FIG. 14 shows graphically the broad angle reflectance of the novel LED device when the first electromagnetic signal has a wavelength of about 460 nm architecture as compared with prior art devices.

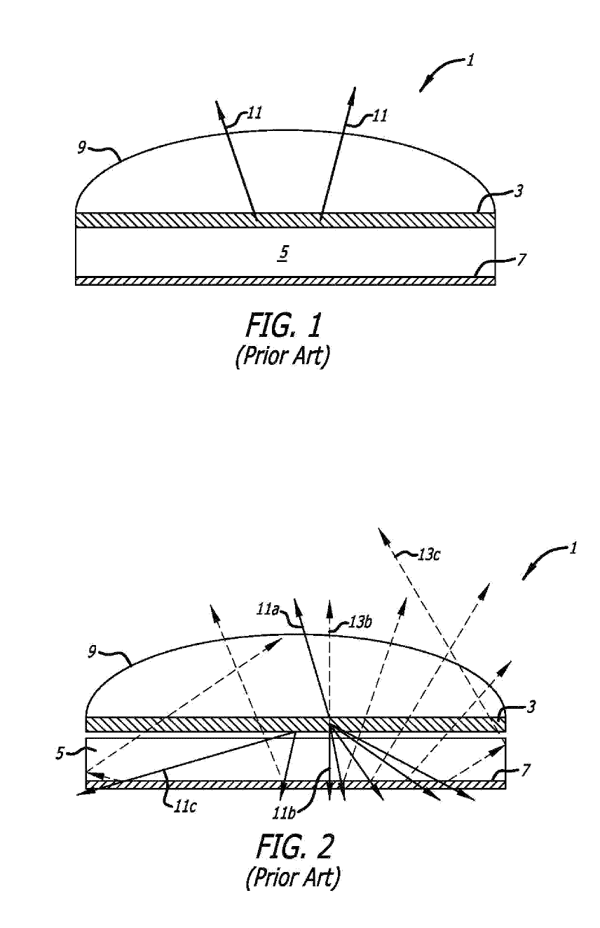

### DETAILED DESCRIPTION

FIG. 4 shows a cross-sectional view of an embodiment of a high power LED device. As shown, the improved LED device 20 includes at least one active layer 22 positioned on or proximal to at least one substrate 24. In one embodiment, the active layer 22 comprises a light-producing active layer. Optionally, a single light-producing active layer 22 may be positioned on the substrate 24. Optionally, any number of active layers 22 may be positioned on the substrate 24. As such, the active layer 22 may comprise a multi quantum well device or structure. It should be noted that the active layer 22 may be in communication with at least one energy source and, thus, may include at least one electrical connection device (not shown) configured to provide at least one electrical signal to thereto. Further, in one embodiment the substrate 24 comprises a silicon carbide substrate. Optionally, any variety of materials may be used to form the substrate 24. Exemplary substrate materials include, without limitations, silica, sapphire, various composite materials, and the like. Further, the substrate 24 may be configured to transmit substantially all electromagnetic radiation therethrough.

Referring again to FIG. 4, like the prior art devices, the present LED device 20 may include at least one metal layer or bonding material 28 applied thereto (hereinafter metal layer and bonding material may be used interchangeably). In one embodiment, the metal layer comprises aluminum. In an alternate embodiment, the metal layer 28 comprises a thermal paste or similar bonding material configured to enable the LED to be coupled to a material substrate. Exemplary material substrates include, without limitations, printed circuit boards and the like. Like the prior art devices, the metal layer or bonding material 28 is configured to reflect rear-emitted electromagnetic radiation to at least one doped encapsulation device 30 positioned proximate to the active layer 22, while aiding the effective removal of heat from the LED device 20. However, unlike prior art devices, the improved LED device 20 disclosed in the present application includes at least one coating layer 26 applied to a surface of the substrate 24. In one embodiment, a metal layer or bonding material 28 may be applied to the coating layer 26 positioned on the substrate 24. The inclusion of the coating layer 26 on the improved LED device 20 disclosed in the present application is configured to achieve optimum light reflectivity of substantially all light within substrate 24, at all possible angles of incidence 0 degrees-90 degrees, thereby increasing the output of the LED device 20.

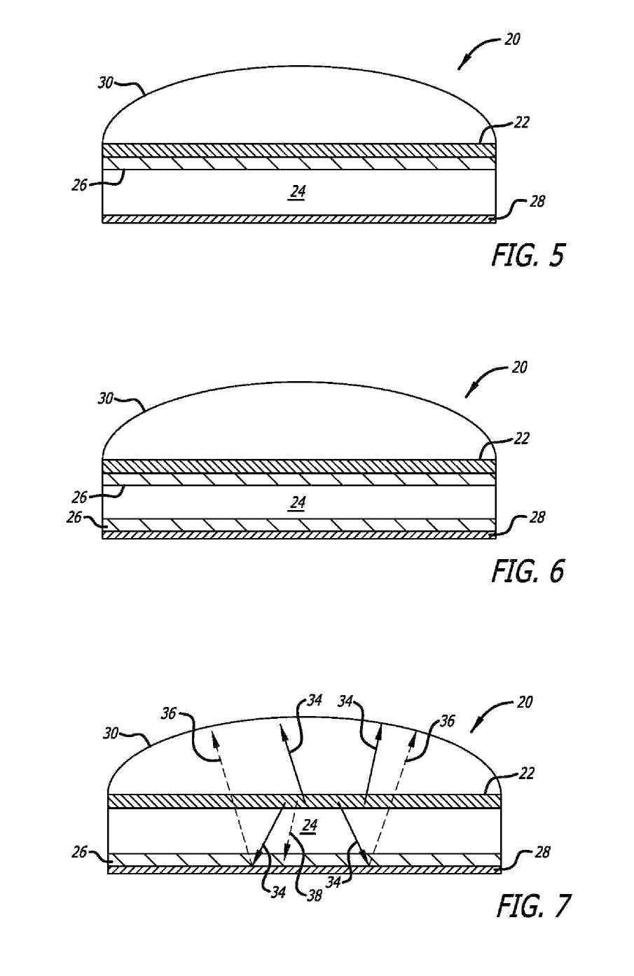

Optionally, the coating layer 26 may be applied to any surface of the substrate 24, the metal layer or bonding material 28, or both, and need not be positioned therebetween. For example, FIG. 5 shows an LED configuration having a coating layer 26 positioned proximate to the active layer 22. In contrast, FIG. 6 shows an LED configuration having a first coating layer 26 located proximate to the active layer 22 and a second coating layer 26 positioned proximate to the substrate 24 and metal layer 28. Referring to FIGS. 5 and 6, positioning a coating layer 26 proximate to the active layer 22 may increase LED illumination by eliminating light losses due to internal substrate light scatter and light-piping (losses through the LED chip edges). As a result, the present embodiment offers improved performance over prior art devices by efficiently reflecting the desired UV or visible light produced by the active layer 22 therethrough while transmitting the damaging longer wavelength infrared radiation through the substrate 24 to be eventually removed by via the optional metal layer 28 and/or a heatsink coupled thereto. In one embodiment, the method for applying the coating layer 26 produces a stable, hard, dense, nonporous amorphous coating that does not substantially absorb moisture, which could otherwise compromise device quality, longevity and performance.

Referring again to FIG. 4, the coating layer 26 may be comprised of any variety or number of materials. For example, in one embodiment the coating layer 26 comprises alternating layers of materials having a high index of refraction (hereinafter “high index”) and materials having a low index of refraction (hereinafter “low index”). Optionally, the coating layer 26 may comprise one or more dielectric materials. Exemplary high index materials include, without limitations, Ta₂O₅, HfO₂, TiO₂, Nb₂O₅, and the like. Exemplary low index materials include, without limitations, SiO₂, Al₂O₃, and the like. For example, in one embodiment coating layer 26 may be configured to reflect at least 90% of electromagnetic radiation having wavelength from about 430 nm to about 500 nm at all angles from about 0 degree to about 90 degrees. In another embodiment, the coating layer 26 may be configured to reflect at least about 95% of electromagnetic radiation having wavelength from about 430 nm to about 500 nm at all angles from about 0 degree to about 90 degrees. In still another embodiment, the coating layer 26 may be configured to reflect at least about 98% of electromagnetic radiation having wavelength from about 430 nm to about 500 nm at all angles from about 0 degree to about 90 degrees. In another embodiment, the coating layer 26 may be configured to reflect at least about 99% of electromagnetic radiation having wavelength from about 430 nm to about 500 nm at all angles from about 0 degree to about 90 degrees. As such, the coating layer 26 may be configured to optimize reflection of any desired wavelength band at all incident angles from about 0 degree to about 90 degrees. Those skilled in the art will appreciate that the coating layer 26 may be configured to selectively reflect at least about 95% of electromagnetic radiation at all angles from about 0 degree to about 90 degrees within any variety of desired wavelength ranges.

In addition to enhancing the reflectivity of the reflective aluminum layer 28, in some embodiments it may be desirable to maximize the extraction of heat from the LED device 20, thereby decreasing the likelihood of heat-related failure. Such improved thermal management also allows for an increase in the amount of power that can be applied to the LED device 20, leading to a further increase in brightness. The heat generated by the active layer 22 during use may be directed through substrate 24 to be eventually absorbed and dissipated by the metal layer 28. As stated above, the coating layer 26 may comprise alternating thin films of low index of refraction materials and high index of refraction materials. Such thin films may be of physical thicknesses ranging from about 5 nm to about 1000 nm each. In one embodiment, the sequence of low index and high index materials is configured to optimize the reflectivity. In still another embodiment, the optical coating layer 26 is configured to optimize reflectivity and heat transfer through the coating layer 26 also by employing high thermal conductivity thin film materials. In still another embodiment, the optical coating layer 26 is configured to optimize reflectivity and heat transfer through the coating layer 26 also by employing high thermal conductivity thin film materials along with the use of a high thermal conductivity copper or copper alloy heat sink rather than standard aluminum.

Optionally, the coating layer 26 my be configured to reflect substantially all light of a first wavelength range while transmitting substantially all light of a second wavelength range therethrough. For example, in one embodiment coating layer 26 may be configured to reflect at least 90% of electromagnetic radiation having wavelength from about 430 nm to about 500 nm while transmitting at least 90% of electromagnetic radiation having a wavelength greater than about 750 nm. In another embodiment, the coating layer 26 may be configured to reflect at least about 95% of electromagnetic radiation having wavelength from about 430 nm to about 500 nm while transmitting at least 95% of electromagnetic radiation having a wavelength greater than about 500 nm. In still another embodiment, the coating layer 26 may be configured to reflect at least about 98% of electromagnetic radiation having wavelength from about 430 nm to about 500 nm while transmitting at least 98% of electromagnetic radiation having a wavelength greater than about 750 nm. In another embodiment, the coating layer 26 may be configured to reflect at least about 99% of electromagnetic radiation having wavelength from about 430 nm to about 500 nm while transmitting at least 99% of electromagnetic radiation having a wavelength greater than about 750 nm. As such, the coating layer 26 may be configured to optimize reflection of a desired first wavelength to improve the fluorescence of the doping material in the encapsulation device 30 while reducing the back reflection of electromagnetic radiation at the second wavelength (e.g. infrared radiation) at the substrate-metal layer interface, thereby improving the transfer of heat through the metal layer 28. It is noted that the increased lumens output created by coating layer 26 alternatively allows the LED to be run at a lower applied power, which subsequently reduces heat and thereby extends device lifetime while possibly leading to lower manufacturing costs (e.g. possible elimination of the metal layer and directly bonding the LED chip using a thermal paste).

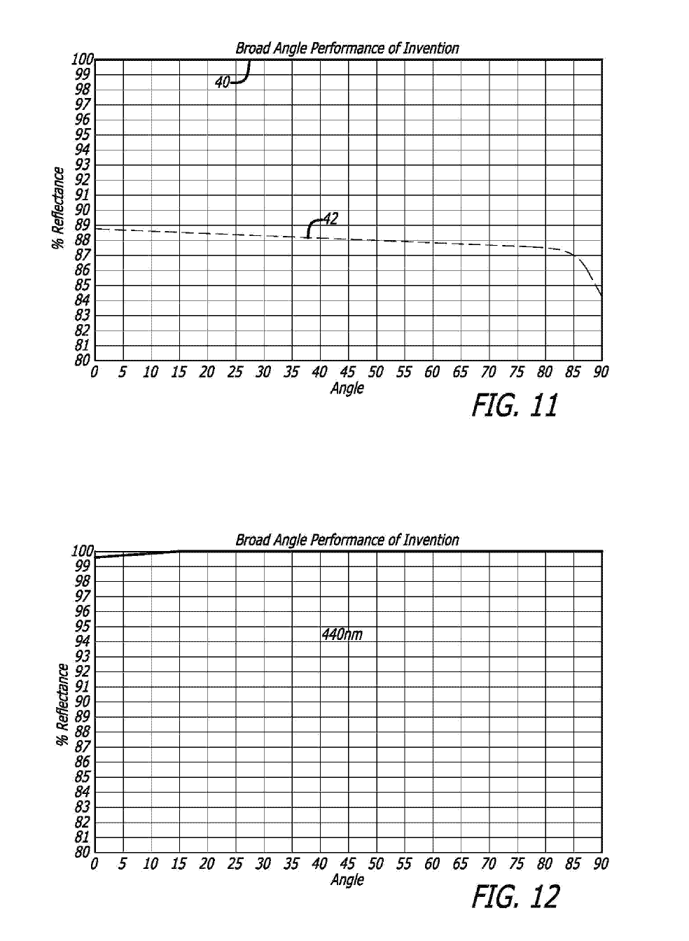

FIG. 11 shows graphically the improved performance characteristics of the device. For all desired LED emission wavelengths (such as within the range of 440 nm-460 nm), the reflectivity performance 40 of the optical coating 26 shown in FIG. 4 achieves greater than 99% for all incident angles 0-90 degrees. As shown in FIG. 11, the reflectivity performance of prior art devices 42 is typically less than 90% which becomes worse with angle.

As shown in FIG. 4, at least one encapsulation device 30 may be positioned on the improved LED device 20. The encapsulation device 30 may include any variety of dopants or doping materials therein. For example, in one embodiment the encapsulation device 30 includes phosphor configured to fluoresce white light when irradiated with electromagnetic radiation having a wavelength range of about 400 nm to about 525 nm. In another embodiment, the encapsulation device including one or more doping materials configured to fluoresce and emit light at any variety of wavelengths when illuminated with electromagnetic radiation of any wavelength emitted by the active layer 22. Optionally, multiple doping materials may be used simultaneously. The encapsulation device 30 may be formed in any variety of ways. For example, in one embodiment the encapsulation device 30 comprises an epoxy material applied as a fluid to the active layer 22. In another embodiment, the encapsulation device 30 may comprise a physical structure bonded to or otherwise secured to the active layer 22. For example, in one embodiment the encapsulation device 30 may form an optical lens. Exemplary optical lenses include, without limitations, concave lenses, convex lenses, fresnel lenses, and the like. In one embodiment, the encapsulation device 30 is configured to couple to the improved LED device 20 in sealed relation. For example, the encapsulation device 30 may be coupled to the improved LED device 20 in hermetically sealed relation.

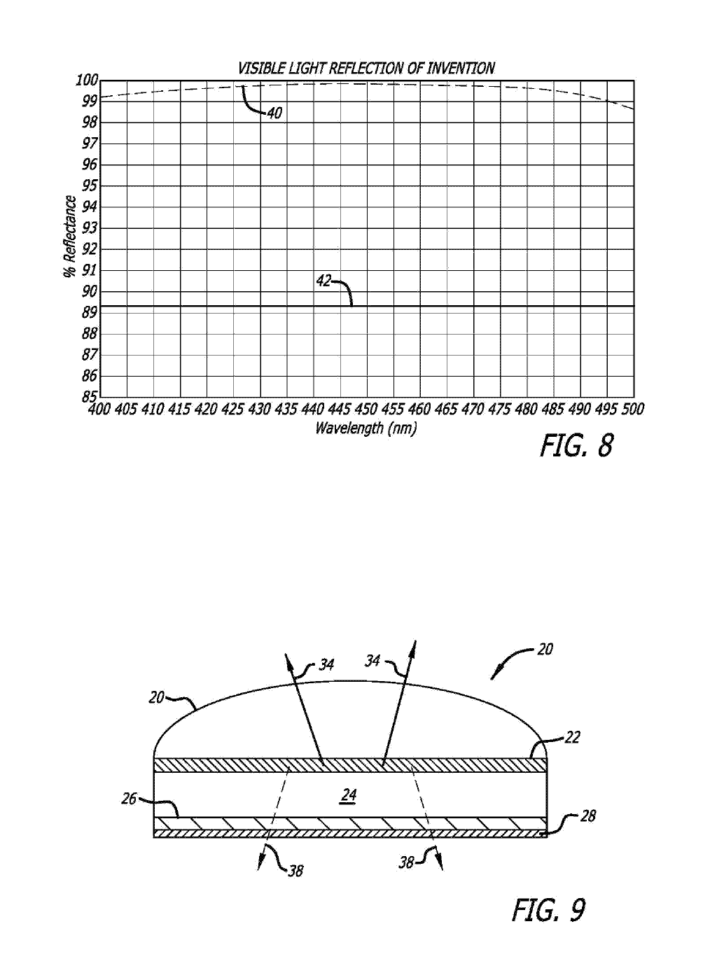

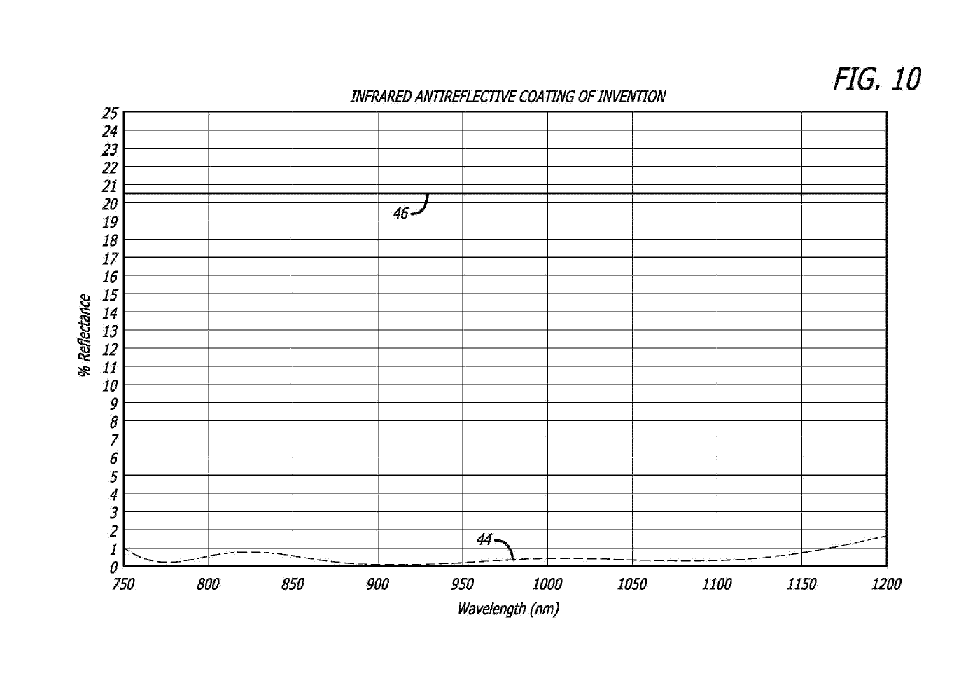

FIGS. 7 and 9 show cross-sectional views of an embodiment of an improved LED device 20 during use, while FIGS. 8 and 10 show graphically the improved performance characteristics of the illustrated device. As shown in FIGS. 7 and 9, the active layer 22 may emit electromagnetic radiation at multiple wavelengths or multiple wavelength ranges. For example, in the illustrated embodiments, the active layer 22 emits a first electromagnetic signal 34 at a first wavelength range of about 430 nm to about 470 nm (visible blue light) and a second electromagnetic signal 38 at a second wavelength range of greater than about 750 nm. In one embodiment, the wavelength of the first electromagnetic signal 34 will be configured to fluoresce the doping materials in the encapsulation device 30. In the illustrated embodiment, the first and second electromagnetic signals 34, 38 are emitted simultaneously, although those skilled in the art will appreciate that the electromagnetic signals may be emitted sequentially.

Referring to FIG. 7, the active layer 22 may be configured to emit at least a portion of the first electromagnetic signal 34 omni-directionally. As such, a portion of the first electromagnetic signal 34 will be directed to the encapsulation device 30 coupled to improved LED device 20, thereby resulting in the fluorescence of the doping materials in the encapsulation device. Further, as shown in FIG. 7, at least a portion of the first electromagnetic signal 34 will be emitted through the substrate 24 to the coating layer 26. As stated above, the coating layer 26 is configured to reflect substantially all light within a chosen wavelength range while transmitting substantially all light outside the chosen wavelength range therethrough. In the illustrated embodiment, the coating layer 26 is configured to reflect at least 98% of incident electromagnetic radiation within the wavelength range of about 425 nm to about 475 nm. As such, substantially all of the first signal 34 incident upon the coating layer 26 will be reflected by the coating layer 26 producing a reflected first electromagnetic signal 36. The reflected signal 36 traverses through the substrate 24 and active layer 24 and is incident on the encapsulation device 30, resulting in fluorescence of the doping material included therein. Unlike prior art devices which included an aluminum, silver, copper or other metal layer capable of reflecting about 85% of an electromagnetic signal incident thereon, the coating layer 26 of the improved LED device described herein is configured to reflect substantially all (i.e. greater than about 98%) of the first electromagnetic signal 34 at all possible angles, thereby greatly improving the brightness of the device. FIG. 8 shows graphically the improved reflectance 40 enabled by the inclusion of the coating layer 26 at the first electromagnetic signal 34 (typically greater than 99.9% in the critical wavelength region 440 nm-460 nm for a blue/white LED) as compared to the typical 85%-90% reflectance 42 of current art devices.

As shown in FIG. 9, the second electromagnetic signal 38 may also be emitted omni-directionally. At least a portion of the second electromagnetic signal 38 traverses through the substrate 24 and is incident on the coating layer 26. As stated above, the coating layer 26 may be configured to transmit substantially all (i.e. greater than 98%) of the second electromagnetic signal 38 having a wavelength range of greater than about 750 nm. As such, coating layer 26 may be configured to transmit substantially all infrared radiation generated by the active layer 22 incident thereon to the metal layer 28 (which subsequently absorbs and dissipates the infrared heat). As such, the improved LED device is configured to more efficiently remove infrared radiation (i.e. heat) therefrom, thereby providing a more thermally efficiently LED device then presently available. It is noted that the increased lumens output created by coating layer 26 alternatively allows the LED to be run at a lower applied power, which subsequently reduces heat and thereby extends device lifetime. FIG. 10 shows graphically the optimized infrared anti-reflectance performance 44 of the improved LED device 20 (typically less than 0.5% average reflectance 750 nm-1200 nm), along with the typical undesirable high infrared back-reflectance performance 46 of a current LED device, having, for example a SiC substrate.

### EXAMPLE

An exemplary device employing the architecture described above was manufactured for testing. The device was manufactured as illustrated in FIG. 4 having a multilayer dielectric optical coating 26 uniformly applied directly onto the entire rear surface of a 2″DIA Sapphire substrate 24 upon which individual LED multilayer semiconductor elements 22 were epitaxially grown on its upper surface (individual die sizes were less than about 1.0 mm square). The optical coating 26 was applied before the encapsulation device 30 was applied. A hybrid sputtering optical coating process was employed to deposit alternating high-and-low refractive index thin films having physical thicknesses chosen to optimize the resultant spectral performance desired (maximum optical reflection within a select visible wavelength band 440 nm-460 nm, and maximum heat transmission in the 750 nm-1200 nm range). More specifically, a titanium oxide alloy of refractory metal oxides was employed for the high index material and silicon dioxide was employed as the low index material. A representative multilayer optical coating is as follows (in this case, a sapphire substrate was employed):

Epitaxial Semiconductor LED Layers/Sapphire Substrate/30.32H 68.97L 28.28H (21.26H 76.29L 21.26H)5 17.53H 200.84L

Where the symbols L and H signify the physical thicknesses (in nm) of L (low index) and H (high index) thin films. Representative reflectance performance spectra are illustrated in FIG. 8 and FIG. 10.

As depicted in FIG. 4, a heat-dissipating layer of metal 28 (e.g. aluminum) was subsequently deposited to a thickness that achieves optical opacity (thicknesses typically 50 nm-500 nm) using deposition techniques known in the art. For example, the metal layer 28 may be applied using, thermal deposition techniques, sputtering techniques, or other techniques generally known in the art. Optionally, the metal layer may be omitted and heat-sinking by directly using a high thermal conductivity paste may be used. The final coated wafer is then diced into individual elements, mounted onto the appropriate assembly with the required wire bonds and encapsulated with a chosen epoxy.

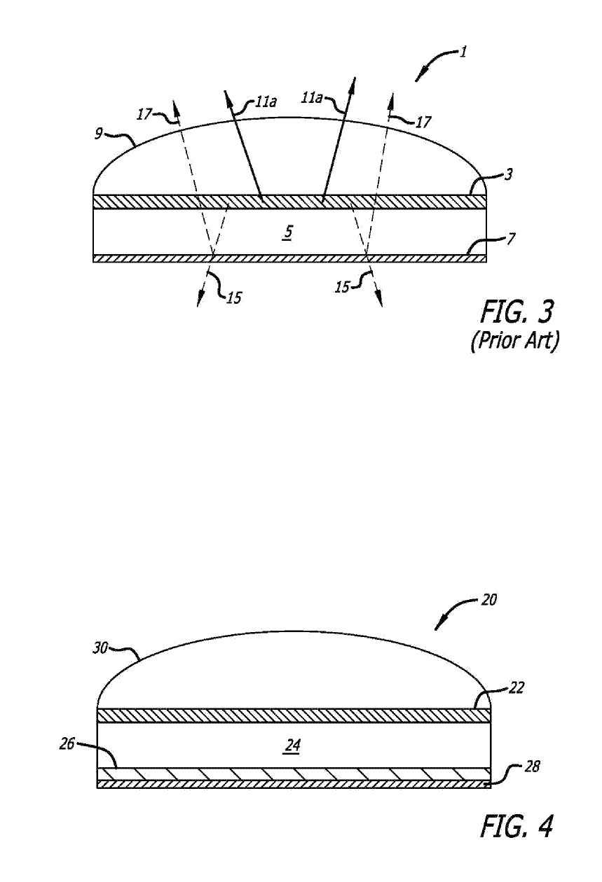

FIG. 11 shows graphically the improved performance characteristics of the device. For all desired LED emission wavelengths (such as within the range of 440 nm-460 nm), the reflectivity performance 40 of the optical coating 26 of the invention (FIG. 4) achieves greater than 99% for all incident angles 0-90 degrees. As shown in FIG. 8, the reflectivity performance of prior art devices 42 is typically less than 90% (layer 7 of FIG. 3), which becomes worse with angle.

As shown in FIG. 7, the reflected electromagnetic signal 36 traverse through the substrate 24 and light producing layer 22 and is incident on the encapsulation device 30, resulting in fluorescence of the doping material included therein. Unlike prior art devices which included an aluminum layer capable of reflecting less than about 89% of an electromagnetic signal incident thereon, the coating layer 26 of the improved LED device 20 described herein is configured to reflect substantially all (i.e. greater than about 99%) of the electromagnetic signal 34 at all angles 0-90 degrees, thereby greatly improving the brightness of the device.

### Example 2

An exemplary device employing the architecture described herein was manufactured for testing. In this embodiment, as illustrated in FIG. 4, a multilayer dielectric optical coating 26 was uniformly applied directly onto the entire rear surface of a 2″DIA sapphire substrate 24 upon which individual LED multilayer semiconductor elements 22 were epitaxially grown on its upper surface (individual die sizes were less than about 1.0 mm square). In this case, the LED emits a blue light within the wavelength range 440 nm-460 nm. The optical coating 26 was applied before the encapsulation device 30 was applied. Alternating high-and-low refractive index thin films having physical thicknesses chosen to optimize the resultant spectral performance desired were deposited (maximum optical reflection within a select visible wavelength band 440 nm-460 nm). In this specific case, a titanium oxide alloy was employed for the high index material and silicon dioxide was employed as the low index material. A representative multilayer optical coating is as follows:

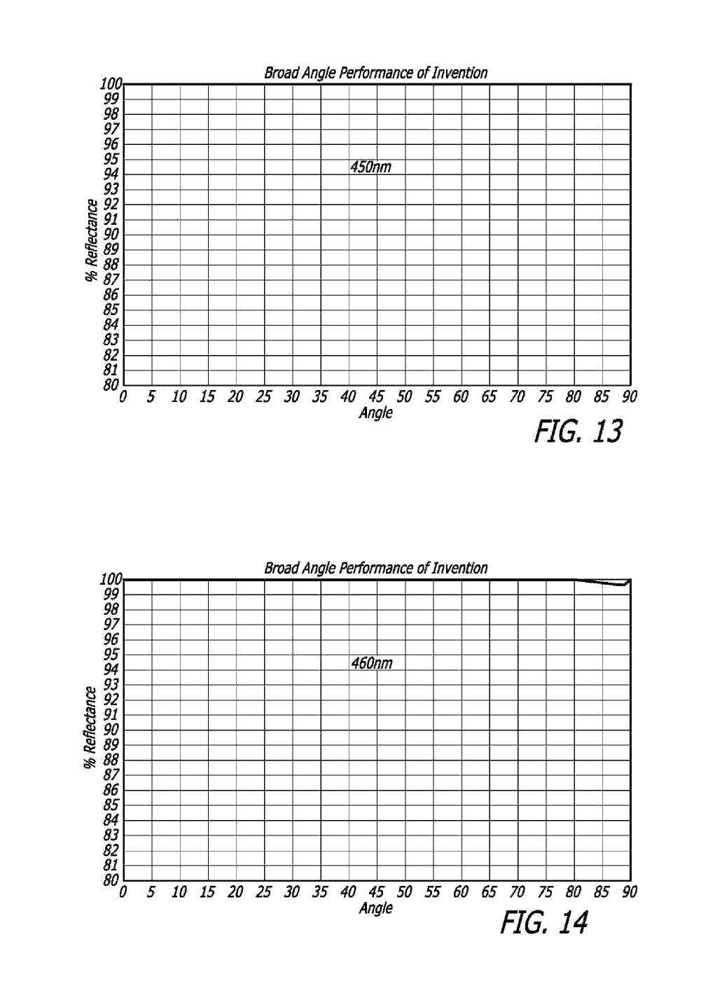

Epitaxial Semiconductor LED Layers/Sapphire Substrate/34.86H 75.92L 32.52H (24.45H 83.98L 24.45H)9 (26.89H 92.38L 26.89H)9 20.16H 221.08L

Where the symbols L and H signify the physical thicknesses (in nm) of L (low index) and H (high index) thin films. Representative reflectance performance spectra as a function of angle are illustrated in FIG. 12 (440 nm), FIG. 13 (450 nm) and FIG. 14 (460 nm).

As depicted in FIG. 4, a heat-dissipating layer of aluminum 28 was subsequently deposited to a thickness that achieves optical opacity (thicknesses typically 50 nm-500 nm). Again, the metal film may be optionally omitted (the die is bonded to the final assembly by using a high thermal conductivity paste). The final coated wafer is then diced into individual elements, mounted onto the appropriate assembly with the required wire bonds and encapsulated with a chosen epoxy.

While particular forms of embodiments have been illustrated and described, it will be apparent that various modifications can be made without departing from the spirit and scope of the embodiments of the invention.

What is claimed is:

1. An improved LED device, comprising:
at least one active layer in communication with an energy source and configured to emit a first electromagnetic signal within a first wavelength range and at least a second electromagnetic signal within at least a second wavelength range;
a substrate configured to support the active layer;
at least one coating layer applied to a surface of the substrate, the coating layer configured to reflect at least 95% of the first electromagnetic signal at the first wavelength range and transmit at least 95% of the second electromagnetic signal at the second wavelength range; and
an encapsulation device positioned to encapsulate the active layer.

2. The device of claim 1 wherein the active layer comprises a multi-quantum well device.

3. The device of claim 1 wherein the substrate comprises sapphire.

4. The device of claim 1 wherein the substrate comprises silica.

5. The device of claim 1 wherein the substrate comprises silicon carbide.

6. The device of claim 1 wherein the coating layer comprises alternating layers of materials having a high index of refraction and a low index of refraction.

7. The device of claim 6 wherein the high index material is selected from the group consisting of Ta₂O₅, HfO₂, TiO₂, and Nb₂O₅.

8. The device of claim 6 wherein the low index material comprises SiO₂.

9. The device of claim 6 wherein the low index material comprises Al₂O₃.

10. The device of claim 1 wherein the coating layer comprises alternating layers of TiO₂ and SiO₂.

11. The device of claim 1 wherein the first wavelength range is from about 430 nm to about 500 nm.

12. The device of claim 1 wherein the second wavelength is greater than about 500 nm.

13. The device of claim 1 further comprising:
a first coating layer positioned between the active layer and the substrate,
at least a second coating layer applied to an opposing surface of the substrate; and
a metal layer applied to the second coating layer.

14. The device of claim 1 further comprising a metal layer applied to the coating layer.

15. The device of claim 14 wherein the metal layer comprises aluminum.

16. The device of claim 14 wherein the metal layer comprises copper.

17. The device of claim 1 further comprising a bonding material positioned between the coating layer and a support structure configured to couple the LED device to the material structure.

18. The device of claim 1 wherein the encapsulation device includes at least one dopant therein.

19. The device of claim 18 wherein the dopant is configured to fluoresce when illuminated with the first electromagnetic signal within the first wavelength range.

20. The device of claim 18 wherein the dopant comprises phosphor.

21. An improved LED device, comprising:
at least one active layer in communication with an energy source and configured to emit a first electromagnetic signal within a first wavelength range and at least a second electromagnetic signal within at least a second wavelength range;
a substrate configured to support the active layer;
at least one coating layer applied to a surface of the substrate, the coating layer configured to reflect at least 95% of the first electromagnetic signal at the first wavelength range at all angles from about 0 degree to about 90 degrees and transmit at least 95% of the second electromagnetic signal at the second wavelength range;
at least one metal layer applied to the coating layer and configured to transmit the second electromagnetic signal at the second wavelength therethrough; and
an encapsulation device positioned to encapsulate the active layer.

22. The device of claim 21 wherein the active layer comprises a multi-quantum well device.

23. The device of claim 21 wherein the substrate comprises sapphire.

24. The device of claim 21 wherein the substrate comprises silica.

25. The device of claim 21 wherein the coating layer comprises alternating layers of materials having a high index of refraction and a low index of refraction.

26. The device of claim 25 wherein the high index material is selected from the group consisting of Ta₂O₅, HfO₂, TiO₂, and Nb₂O₅.

27. The device of claim 25 wherein the low index material comprises SiO₂.

28. The device of claim 25 wherein the low index material comprises Al₂O₃.

29. The device of claim 21 wherein the coating layer comprises alternating layers of TiO₂ and SiO₂.

30. The device of claim 21 wherein the first wavelength range is from about 430 nm to about 500 nm.

31. The device of claim 21 wherein the second wavelength is greater than about 500 nm.

32. The device of claim 21 further comprising a first coating layer positioned between the active layer and the substrate and at least a second coating layer positioned between substrate and the metal layer.

33. The device of claim 21 wherein the metal layer comprises aluminum,

34. The device of claim 21 wherein the metal layer comprises copper.

35. The device of claim 21 wherein the encapsulation device includes at least one dopant therein.

36. The device of claim 35 wherein the dopant is configured to fluoresce when illuminated with the first electromagnetic signal within the first wavelength range.

37. The device of claim 35 wherein the dopant comprises phosphor.

38. A method of manufacturing an LED device, comprising:
growing an epitaxial layer capable of emitting electromagnetic radiation within a first wavelength range and at least a second electromagnetic radiation within at least a second wavelength range when subjected to an electric charge on a substrate;
applying at least one coating layer configured to reflect at least 95% of the first electromagnetic signal at the first wavelength range and transmit at least 95% of the second electromagnetic signal at the second wavelength range to a surface of the substrate; and
encapsulating at least the active layer within an encapsulation device.

39. The method of claim 38 further comprising forming the coating layer by applying alternating layers of high index of refraction materials and low index of refraction materials to the substrate.

40. A method of manufacturing an LED device, comprising:
growing an epitaxial layer capable of emitting electromagnetic radiation within a first wavelength range and at least a second electromagnetic radiation within at least a second wavelength range when subjected to an electric charge on a substrate;
applying at least one coating layer configured to reflect at least 95% of the first electromagnetic signal at the first wavelength range and transmit at least 95% of the second electromagnetic signal at the second wavelength range to a surface of the substrate;
applying at least one metal layer to the coating layer; and
encapsulating at least the active layer within an encapsulation device.

41. The method of claim 40 further comprising forming the coating layer by applying alternating layers of high index of refraction materials and low index of refraction materials to the substrate.

42. The method of claim 43 further comprising applying a first coating layer between the substrate prior to growing the epitaxial layer thereon, an applying a second coating layer to the opposite surface of the substrate to receive the metal layer thereon.
